(19) United States
(12) Patent Application Publication
(10) Pub. No.: US 2025/0219583 A1
(43) Pub. Date: Jul. 3, 2025

(54) POWER AMPLIFIER SYSTEM WITH DYNAMIC HEADROOM GENERATOR

(71) Applicant: MEDIATEK INC., Hsinchu City (TW)

(72) Inventors: Yi-Wei Huang, Hsinchu City (TW); Yi-Han Pan, Hsinchu City (TW); Chun-Lung Chang, Hsinchu City (TW); Sung-Han Wen, Hsinchu City (TW); Kuan-Hung Chen, Hsinchu City (TW); Chia-Feng Chiang, Hsinchu City (TW); Kuan-Ta Chen, Hsinchu City (TW)

(73) Assignee: MEDIATEK INC., Hsinchu City (TW)

(21) Appl. No.: 18/969,320

(22) Filed: Dec. 5, 2024

Related U.S. Application Data
(60) Provisional application No. 63/614,947, filed on Dec. 27, 2023.

(51) Int. Cl. H03F 1/02; H03F 3/181; H03F 3/24

(52) U.S. Cl. CPC H03F 1/0227; H03F 3/181; H03F 3/24; H03F 2200/03; H03F 2200/102; H03F 2200/504

(57) ABSTRACT

The present invention provides a power amplifier system configured to receive an input audio signal to generate an output audio signal is disclosed. The power amplifier system includes a reference signal generator, a dynamic headroom generator and a DC-DC converter. The reference signal generator is configured to generate a reference signal according to the input signal. The dynamic headroom generator is configured to generate an output reference signal according to the reference signal and a change rate of a signal, wherein the signal is the reference signal, the input audio signal, or correlated with the reference signal or the input audio signal. The DC-DC converter is configured to generate a supply voltage to a power amplifier, wherein a voltage level of the supply voltage is determined according to the output reference signal, and the power amplifier is configured to generate the output audio signal according to the input audio signal.

### CROSS REFERENCE TO RELATED APPLICATIONS

This application claims the benefit of U.S. Provisional Application No. 63/614,947, filed on Dec. 27, 2023. The content of the application is incorporated herein by reference.

### BACKGROUND

In a transmitter such as an audio signal transmitter of a portable electronic device, a power amplifier generally requires much power to amplify a low-power audio signal into a high-power audio signal. To lower power consumption of the power amplifier, an envelope tracking modulator is used to track the signal envelope to dynamically adjust a supply voltage of the power amplifier and related circuits. Mostly, a voltage of the audio signal does not increase fast, so the headroom (i.e., difference between the supply voltage and the audio signal voltage) can be small for low power consumption. On few occasions, however, if a voltage of the audio signal increases too fast (that is, the sound volume and/or frequency represented by the audio signal increases too fast), the supply voltage may not increase in time to keep up with the voltage increase of the audio signal, causing the audio signal outputted by the power amplifier to be distorted and affecting the audio quality.

### SUMMARY

It is therefore an objective of the present invention to provide an audio amplifier system, which determines a voltage level of the supply voltage based on a change rate of the audio signal in a real-time manner, to solve the above-mentioned problems.

According to one embodiment of the present invention, a power amplifier system configured to receive an input audio signal to generate an output audio signal is disclosed. The power amplifier system comprises a reference signal generator, a dynamic headroom generator and a DC-DC converter. The reference signal generator is configured to generate a reference signal according to the input audio signal. The dynamic headroom generator is configured to generate an output reference signal according to the reference signal and a change rate of a signal, wherein the signal is the reference signal, the input audio signal, or correlated with the reference signal or the input audio signal. The DC-DC converter is configured to generate a supply voltage to a power amplifier, wherein a voltage level of the supply voltage is determined according to the output reference signal, and the power amplifier is configured to generate the output audio signal according to the input audio signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an audio amplifier system according to one embodiment of the present invention.

FIG. 2 shows increasing the level of the output reference signal to accelerate the increase of the supply voltage to prevent the supply voltage from clipping the output audio signal.

FIG. 3 is a diagram illustrating the dynamic headroom generator according to one embodiment of the present invention.

FIG. 4 is a diagram showing the output reference signal generated by the dynamic headroom generator according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

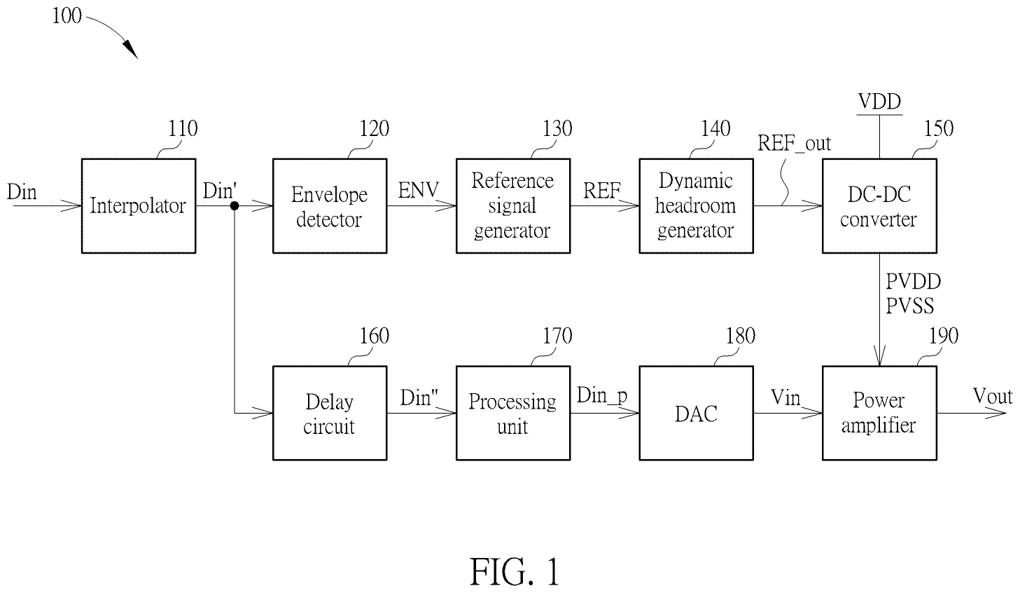

FIG. 1 is a diagram illustrating an audio amplifier system 100 according to one embodiment of the present invention, wherein the audio amplifier system 100 is configured to receive a digital input audio signal Din to generate a high-power audio output signal Vout to a headphone or speaker. As shown in FIG. 1, the audio amplifier system 100 comprises an interpolator 110, an envelope detector 120, a reference signal generator 130, a dynamic headroom generator 140, a DC-DC converter 150, a delay circuit 160, a processing unit 170, a digital-to-analog converter (DAC) 180 and a power amplifier 190. In this embodiment, all the components in FIG. 1 are implemented by circuit elements.

In the operation of the audio amplifier system 100, firstly, the interpolator 110 receives and up-samples the digital input audio signal Din to generate an up-sampled audio signal Din′. In other words, the interpolator increases the sampling frequency of the digital input audio signal Din from a lower frequency to a higher frequency, such as from 48 kHz to 384 kHz, to generate the up-sampled audio signal Din′. The envelope detector 120 measures an envelope of the up-sampled audio signal Din′ to generate an envelope detection result ENV. For example, the envelope detector 120 may compute an absolute value of the up-sampled audio signal Din′ to obtain the envelope detection result ENV. The reference signal generator 130 is configured to generate a reference signal REF according to the envelope detection result ENV, wherein the reference signal REF represents a voltage level of a supply voltage PVDD that is used for the power amplifier 190. In one embodiment, the reference signal generator 130 may use a lookup table, which records multiple envelope values and corresponding reference values, to obtain the corresponding reference signal REF based on the envelope detection result ENV. The dynamic headroom generator 140 is configured to adjust the reference signal REF to generate an output reference signal REF_out according to a change rate of the reference signal REF, a change rate of the envelope detection result ENV, or a change rate of any signal whose amplitude is correlated with the reference signal REF or the envelope detection result ENV. Then, the DC-DC converter 150 powered by a supply voltage VDD refers to the output reference signal REF_out to generate the supply voltages PVDD and PVSS for the power amplifier 190, where the supply voltage PVDD may be a positive voltage and the supply voltage PVSS may be a negative voltage.

In a lower path of the audio amplifier system 100, in order to ensure that the supply voltages PVDD and PVSS generated by the DC-DC converter 150 can correspond to the appropriate output audio signal Vout at the correct time, the delay circuit 160 delays the up-sampled audio signal Din′ to generate a delayed audio signal Din″. The processing unit 170 processes the delayed audio signal Din″ to generate a processed audio signal Din_p, and the DAC 180 performs a digital-to-analog conversion operation on the processed audio signal Din_p to generate an analog audio signal Vin. Then, the power amplifier 190 powered by the supply voltages PVDD and PVSS amplifies the analog audio signal Vin to generate the output audio signal Vout.

The main technical feature of this embodiment is the dynamic headroom generator 140, and the operations of the envelope detector 120, the reference signal generator 130, the DC-DC converter 150, the delay circuit 160, the processing unit 170, the DAC 180 and the power amplifier 190 are known by a person skilled in the art, so the following content is only described for the dynamic headroom generator 140.

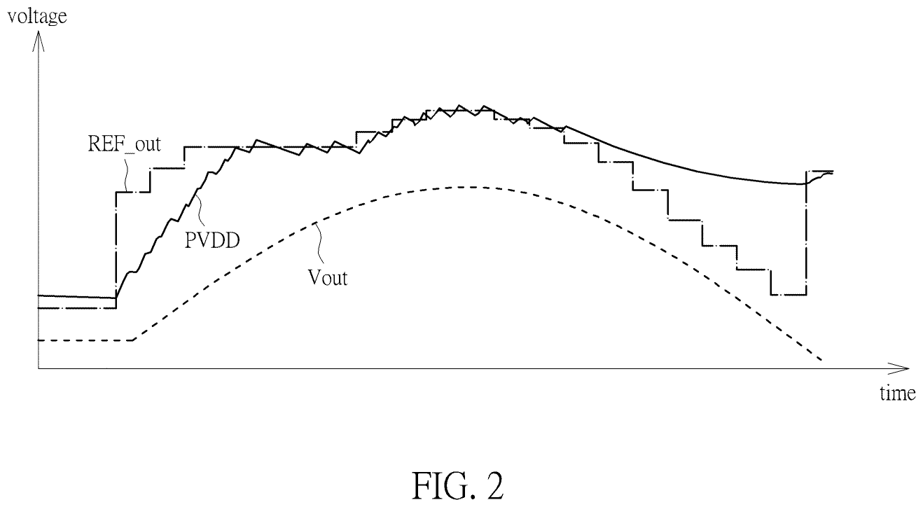

As described in the background of the invention, if a voltage of the audio signal increases too fast, the supply voltage PVDD may not increase in time to keep up with the voltage increase of the audio signal, causing the output audio signal Vout outputted by the power amplifier 190 to be distorted and affecting the audio quality. To solve this problem, the dynamic headroom generator 140 determines the output reference signal REF_out based on the reference signal REF and the change rate of the reference signal REF, the envelope detection result ENV, or any signal whose amplitude is correlated with the reference signal REF or the envelope detection result ENV (in the following description, the change rate of the reference signal REF serves as an example), so that the supply voltage PVDD can rise earlier if it is detected that the reference signal REF has a higher change rate (i.e., the output audio signal Vout will rise fast), to maintain the quality of the output audio signal Vout. In this embodiment, the term “headroom” may indicate a difference between the supply voltage PVDD and the output audio signal Vout. Taking FIG. 2 as an example, when the dynamic headroom generator 140 detects that the reference signal REF has a high change rate, the dynamic headroom generator 140 greatly increases the level of the output reference signal REF_out to accelerate the increase of the supply voltage PVDD before or when the level of the output audio signal Vout begins to increase fast, to prevent the supply voltage PVDD from clipping the output audio signal Vout.

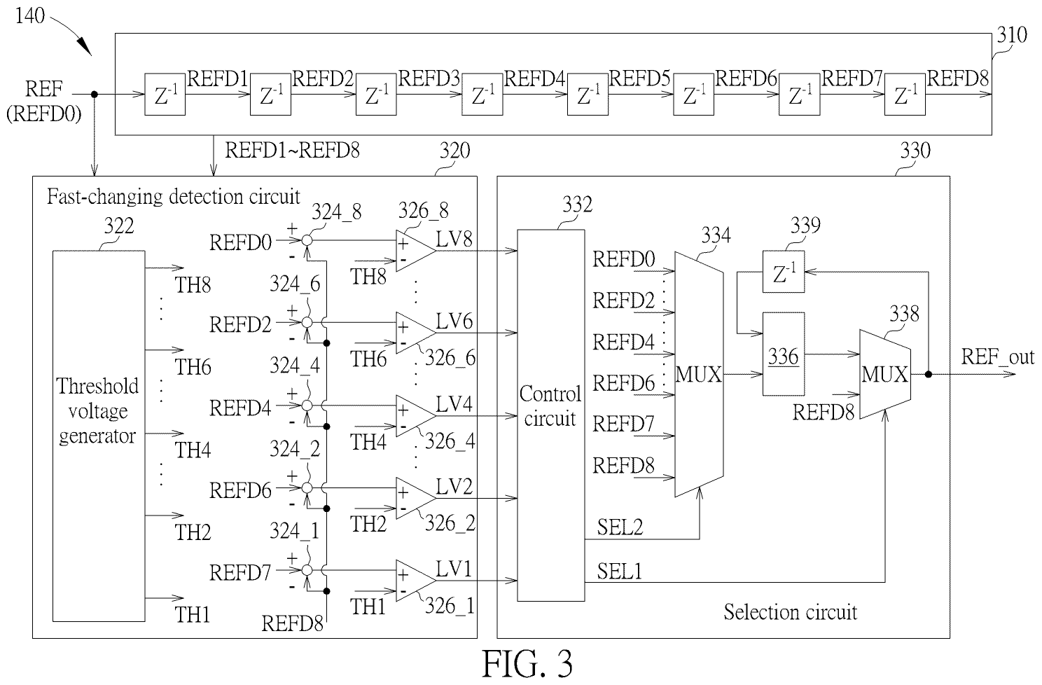

FIG. 3 is a diagram illustrating the dynamic headroom generator 140 according to one embodiment of the present invention. As shown in FIG. 3, the dynamic headroom generator 140 comprises a delay line 310, a fast-changing detection circuit 320 and a selection circuit 330. The delay line 310 comprises multiple delay circuits connected in series (i.e., “z⁻¹” in FIG. 3), and the delay line 310 is used to receive the reference signal REF generated by the reference signal generator 130, and generate multiple delayed reference signals with different delay amount, such as REFD1-REFD8 shown in FIG. 3. In this embodiment, the delayed reference signal REFD8 is closest to the output audio signal Vout that is currently being outputted by the power amplifier 190, while the first reference signal (REF/REFD0) is the farthest from the output audio signal Vout currently being outputted by the power amplifier 190.

The fast-changing detection circuit 320 receives the reference signal REF (which is represented by “REFD0” in the following description) and the delayed reference signals REFD1-REFD8, and detects change rate(s) of the reference signal REF according to the reference signal REFD0 and the delayed reference signals REFD1-REFD8, to generate at least one detection result, wherein the at least one detection result indicates that if the reference signal REFD0 has a fast-changing event. In one embodiment, the fast-changing detection circuit 320 calculates differences between a specific delayed reference signal and the multiple other delayed reference signals, and compares the multiple differences with multiple threshold voltages to generate multiple detection results, respectively, wherein the specific delayed reference signal can be REFD8 that is closest to the output audio signal Vout that is currently being outputted by the power amplifier 190.

Specifically, the fast-changing detection circuit 320 comprises a threshold voltage generator 322, multiple subtractors 324_1-324_8 and multiple comparators 326_1-326_8. The threshold voltage generator 322 is configured to generate multiple threshold voltages TH1-TH8 with different values, wherein the first threshold voltage TH1 to the eighth threshold voltage TH8 are a gradually increasing sequence; that is, the eighth threshold voltage TH8 has the highest value, and the first threshold voltage TH1 has the lowest value. The subtractors 324_1-324_8 are configured to calculate differences between the specific delayed reference signal (i.e. REFD8) and the delayed reference signals REFD7-REFD0, respectively, and the comparators 326_1-326_8 are configured to compare the differences outputted by the subtractors 324_1-324_8 with the threshold voltages TH1-TH8 to generate multiple detection results LV1-LV8, respectively. In this embodiment, each of the detection results indicates if a fast-changing event occurs in the corresponding period. For example, if the difference between the delayed reference signals REFD6 and REFD8 is greater than the threshold voltage TH2, the detection result LV2 will indicate that a period between the delayed reference signals REFD6 and REFD8 has a fast-changing event (i.e., the output audio signal Vout corresponding to a period between the delayed reference signals REFD6 and REFD8 has a fast-changing event); and if the difference between the delayed reference signals REFD6 and REFD8 is not greater than the threshold voltage TH2, the detection result LV2 will indicate that the period between the delayed reference signals REFD6 and REFD8 does not have a fast-changing event. Similarly, if the difference between the delayed reference signals REFD0 and REFD8 is greater than the threshold voltage TH8, the detection result LV8 will indicate that a period between the delayed reference signals REFD0 and REFD8 has a fast-changing event (i.e., the output audio signal Vout corresponding to a period between the delayed reference signals REFD0 and REFD8 has a fast-changing event); and if the difference between the delayed reference signals REFD0 and REFD8 is not greater than the threshold voltage TH8, the detection result LV8 will indicate that the period between the delayed reference signals REFD0 and REFD8 does not have a fast-changing event.

The selection circuit 330 is configured to generate the output reference signal REF_out according to the detection results LV1-LV8. Specifically, the selection circuit 330 selects one of the delayed reference signals REFD0-REFD8 based on the detection result that indicates a longest period of the fast-changing event of the delayed reference signals, and the selected delayed reference signal is used to generate the output reference signal REF_out. For example, if all the detection results LV1-LV8 indicate the fast-changing event, the selection circuit 330 will select the delayed reference signal REFD0 corresponding to the detection result LV8; this indicates that the fast-changing event occurs within a period between the delayed reference signals REFD0 and REFD8. In another example, if only the detection results LV1-LV4 indicate the fast-changing event, the selection circuit 330 will select the delayed reference signal REFD4 corresponding to the detection result LV4; this indicates that the fast-changing event occurs within a period between the delayed reference signals REFD4 and REFD8. In addition, the selection circuit 330 also has a peak-hold mechanism, that is, if the output reference signal REF_out is generated based on the fast-changing event, the output reference signal REF_out will not decrease within the period corresponding to the fast-changing event.

Specifically, the selection circuit 330 comprises a control circuit 332, a multiplexer 334, a maximum value selector 336, a multiplexer 338 and a delay circuit 339. The control circuit 332 is configured to generate a selection signal SEL2 based on the detection result that indicates a longest period of the fast-changing event of the delayed reference signals. For example, if all the detection results LV1-LV8 indicate the fast-changing event, the control circuit 332 generates the selection signal SEL2 to control the multiplexer 334 to output the delayed reference signal REFD0 corresponding to the detection result LV8; this indicates that the fast-changing event occurs within a period between the delayed reference signals REFD0 and REFD8. The maximum value selector 336, the multiplexer 338 and the delay circuit 339 serve as a peak-hold circuit to ensure that the output reference signal REF_out will not decrease (i.e., track and hold the peak value of the output reference signal REF_out) within the period corresponding to the fast-changing event, and the control circuit 332 further generates a selection signal SEL1 to control the multiplexer 338. In detail, if all the detection results LV1-LV8 indicate that there is no fast-changing event, the peak-hold mechanism is not necessary and the control circuit 332 generates the selection signal SEL1 to control the multiplexer 338 to output the delayed reference signal REFD8 as the output reference signal REF_out. If the detection results LV1-LV8 indicate that the fast-changing event occurs, the peak-hold mechanism is enabled and the control circuit 332 generates the selection signal SEL1 to control the multiplexer 338 to output the delayed reference signal determined by the maximum value selector 336, wherein the maximum value selector 336 is used to output the maximum value of the selected delayed reference signal outputted by the multiplexer 334 and a delayed output reference signal generated by using the delay circuit 339 to delay the output reference signal REF_out.

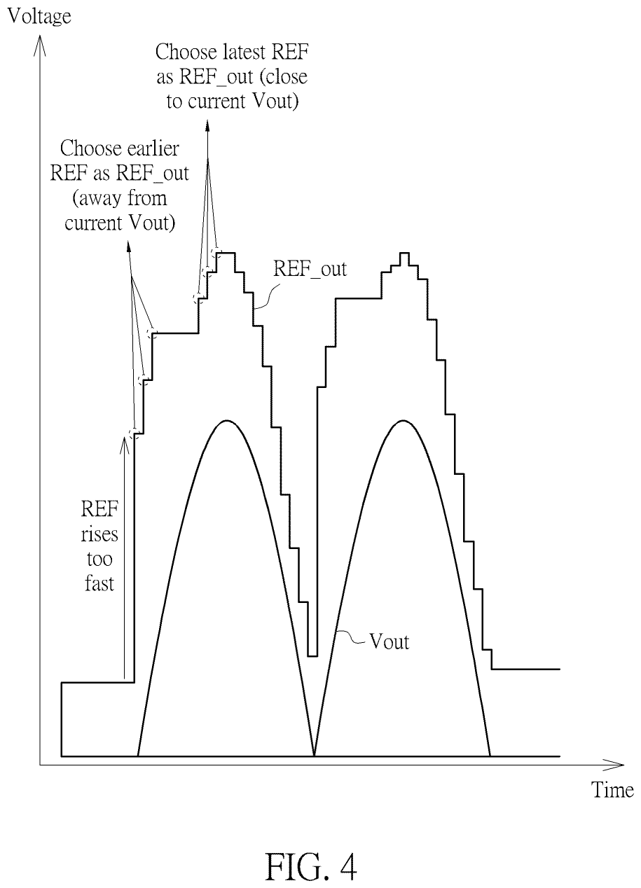

FIG. 4 is a diagram showing the output reference signal REF_out generated by the dynamic headroom generator 140 shown in FIG. 3 according to one embodiment of the present invention. As shown in FIG. 4, when the reference signal REF rises too fast (i.e., has a high change rate), the dynamic headroom generator 140 chooses the earliest reference signal (e.g., REFD0) as the output reference signal REF_out, wherein the earliest reference signal is also regarded as the reference signal REF that is away from the output audio signal Vout currently being outputted by the power amplifier 190. In addition, if the reference signal REF does not rise too fast (i.e., not have a high change rate), the dynamic headroom generator 140 chooses the latest reference signal (e.g., REFD8) as the output reference signal REF_out, wherein the latest reference signal is also regarded as the reference signal that is closest to the output audio signal Vout that is currently being outputted by the power amplifier 190.

It is noted that the detailed structure of the dynamic headroom generator 140 is for illustrative, not a limitation of the present invention. In other embodiments, the number of delayed reference signals, the number of threshold voltages, the number of subtractors, the number of comparators mentioned in FIG. 3 can be determined based on the designer's considerations, and the peak-hold circuit can also have other structures. As long as the output reference signal REF_out can be determined based on the change rate of the reference signal REF, the change rate of the envelope detection result ENV, or the change rate of any signal whose amplitude is correlated with the reference signal REF or the envelope detection result ENV, these alternative designs shall fall within the scope of the present invention.

Briefly summarized, in the power amplifier system of the present invention, by detecting the change rate of the reference signal, and increasing the level of the output reference signal to accelerate the increase of the supply voltage before or when the level of the output audio signal begins to increase fast, the power supply voltage clipping the output audio signal can be prevented.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power amplifier system, configured to receive an input audio signal to generate an output audio signal, comprising:
a reference signal generator, configured to generate a reference signal according to the input audio signal;
a dynamic headroom generator, coupled to the reference signal generator, configured to generate an output reference signal according to the reference signal and a change rate of a signal, wherein the signal is the reference signal, the input audio signal, or correlated with the reference signal or the input audio signal; and
a DC-DC converter, configured to generate a supply voltage to a power amplifier, wherein a voltage level of the supply voltage is determined according to the output reference signal, and the power amplifier is configured to generate the output audio signal according to the input audio signal.

2. The power amplifier system of claim 1, further comprising:
an envelope detector, configured to measure an envelope of the input audio signal to generate an envelope detection result;
wherein the change rage of the signal is the change rate of the reference signal, the change rate of the envelope detection result, or the change rate of the signal correlated with the reference signal or the envelope detection result.

3. The power amplifier system of claim 1, wherein the dynamic headroom generator detects whether the signal has a high change rate; and if the signal has the high change rate, the dynamic headroom generator increases the output reference signal to accelerate an increase of the supply voltage.

4. The power amplifier system of claim 1, wherein the dynamic headroom generator comprises:
a delay line, configured to receive the reference signal to generate multiple delayed reference signals with different delay amount;
a fast-changing detection circuit, configured to receive the reference signal and the delayed reference signals, and detects change rate(s) of the reference signal according to at least a portion of the reference signal and the multiple delayed reference signals, to generate at least one detection result; and
a selection circuit, configured to generate the output reference signal according to the at least one detection result.

5. The power amplifier system of claim 4, wherein the fast-changing detection circuit calculates differences between a specific delayed reference signal and the other delayed reference signals, and compares the multiple differences with multiple threshold voltages to generate multiple detection results, respectively; and the selection circuit generates the output reference signal according to the multiple detection results.

6. The power amplifier system of claim 5, wherein the specific delayed reference signal is one of the multiple delayed reference signals that is closest to the output audio signal that is currently being outputted by the power amplifier.

7. The power amplifier system of claim 5, wherein each of the detection results indicates if a fast-changing event occurs in a corresponding period; and if one or more of the detection results indicate that the fast-changing event occurs, the selection circuit selects one of the delayed reference signals based on the detection result that indicates a longest period of a fast-changing event, and the selected delayed reference signal is used to generate the output reference signal.

8. The power amplifier system of claim 7, wherein if the output reference signal is generated based on the selected delayed reference signal, the selection circuit tracks and holds a peak value of the output reference signal within the period corresponding to the fast-changing event.

9. The power amplifier system of claim 7, wherein if the multiple detection results indicate that there is no fast-changing event, the selection circuit outputs one of the multiple delayed reference signals that is closest to the output audio signal that is currently being outputted by the power amplifier as the output reference signal; and if one or more of the detection results indicate that the fast-changing event occurs, selects a maximum of the selected delayed reference signal and a delayed output reference signal as the output reference signal.
